(19) United States
(12) Patent Application Publication
(10) Pub. No.: US 2024/0416832 A1
(43) Pub. Date: Dec. 19, 2024

(54) ILLUMINATION DEVICE

(71) Applicant: Yazaki Corporation, Tokyo (JP)

(72) Inventors: Tomoki OSANAI, Shizuoka (JP); Naoki Nagaushi, Shizuoka (JP)

(73) Assignee: Yazaki Corporation, Tokyo (JP)

(21) Appl. No.: 18/741,195

(22) Filed: Jun. 12, 2024

(30) Foreign Application Priority Data
Jun. 19, 2023 (JP) 2023-100008

(51) Int. Cl. B60Q 1/50; F21V 23/00

(52) U.S. Cl. CPC B60Q 1/543; F21V 23/001

(57) ABSTRACT

An illumination device includes: a board having a first face and a second face opposite to the first face; a first light source disposed on the first face; a second light source disposed on the second face; and a second wiring pattern disposed on the second face, wherein the second wiring pattern is disposed so as to cover a region on the second face, the region on the second face opposed to a region on the first face with the first light source disposed therein.

### BACKGROUND OF THE INVENTION

### Technical Field

The present invention relates to an illumination device.

### Background Art

Patent Document 1 discloses an illumination device which includes two light emitters used for different purposes, i.e., a first light emitter 13A and a second light emitter 13B, wherein the first light emitter 13A is used as illumination for a charging inlet and the second light emitter 13B is used as an indicator. The illumination device as disclosed in Patent Document 1 is configured such that the first light emitter 13A and the second light emitter 13B are provided on a front side and on a back side of a board 7, respectively.

### CITATION LIST

### Patent Literature

Patent Document 1: JP 2023-42051 A

### SUMMARY OF THE INVENTION

Generally, a board is made of an insulator such as a resin and/or glass and transparent for light. In the case where light sources are arranged on two opposite faces of the board, as is in the illumination device according to Patent Document 1, a light coming from a light source on the front side may e.g. pass through the board to reach the back side of the board. As a result, a user may misrecognize that a light source on the back side of the board were turned on, despite the light source on the back side not being turned on. For example, in the case where the light source on the back side of the board is used as the indicator, as is in the illumination device according to Patent Document 1, the above-described situation may cause a user to misrecognize that the indicator were turned on, despite the light source on the back side emitting no light.

Therefore, an object of the present invention is to provide an illumination device which includes two light sources to be used for different purposes.

In order to achieve the above-mentioned objective, an embodiment of the present invention relates to an illumination device including: a board having a first face and a second face opposite to the first face; a first light source disposed on the first face; a second light source disposed on the second face; and a second wiring pattern disposed on the second face, wherein the second wiring pattern is disposed so as to cover a region on the second face, the region on the second face opposed to a region on the first face with the first light source disposed therein.

The present invention enables an illumination device to be provided which includes two light sources to be used for different purposes.

### BRIEF DESCRIPTION OF THE DRAWINGS

FIG. 1 shows an illumination device 100 according to an embodiment of the present invention;

FIG. 2 shows a view of a board 110 from its first face 111 side;

FIG. 3 shows a view of the board 110 from its second face 112 side;

FIG. 4 shows a sectional view of the board 110 according to FIGS. 2 and 3 along the line AA; and

FIG. 5 shows a sectional view of the board 110 according to FIGS. 2 and 3 along the line BB.

### DETAILED DESCRIPTION OF THE PREFERRED EMBODIMENTS

### <Illumination Device 100>

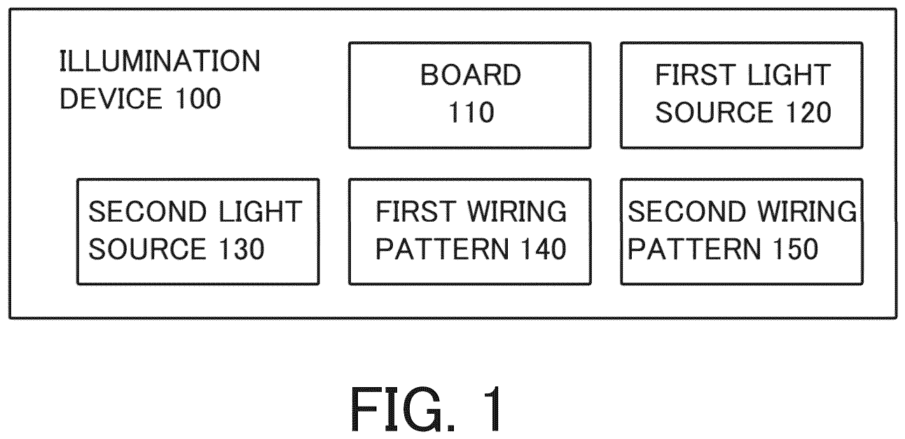

FIG. 1 shows an illumination device 100 according to an embodiment of the present invention. The illumination device 100 includes a board 110, a first light source 120, a second light source 130, first wiring patterns 140, and second wiring patterns 150. For example, the illumination device 100 is configured for illuminating a charging inlet of a vehicle.

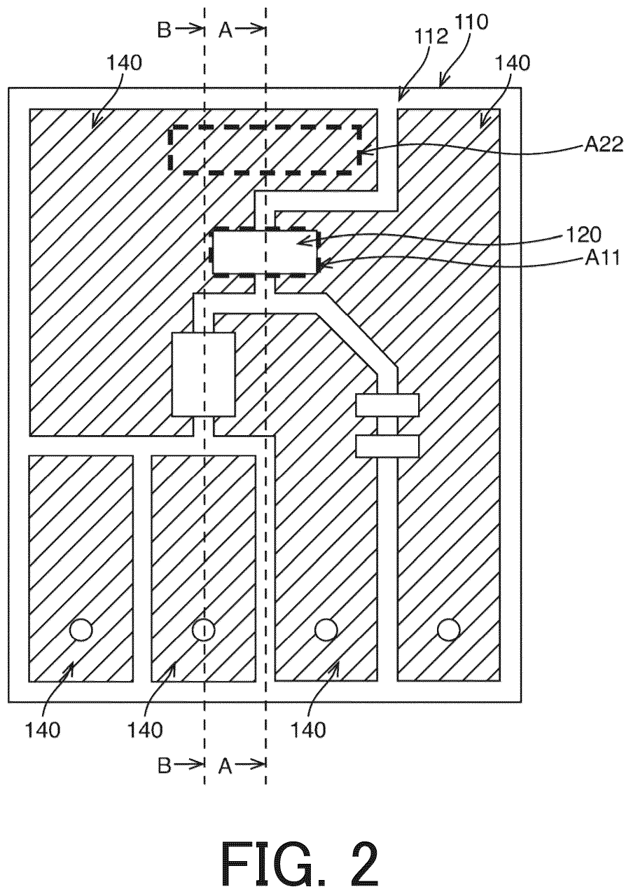

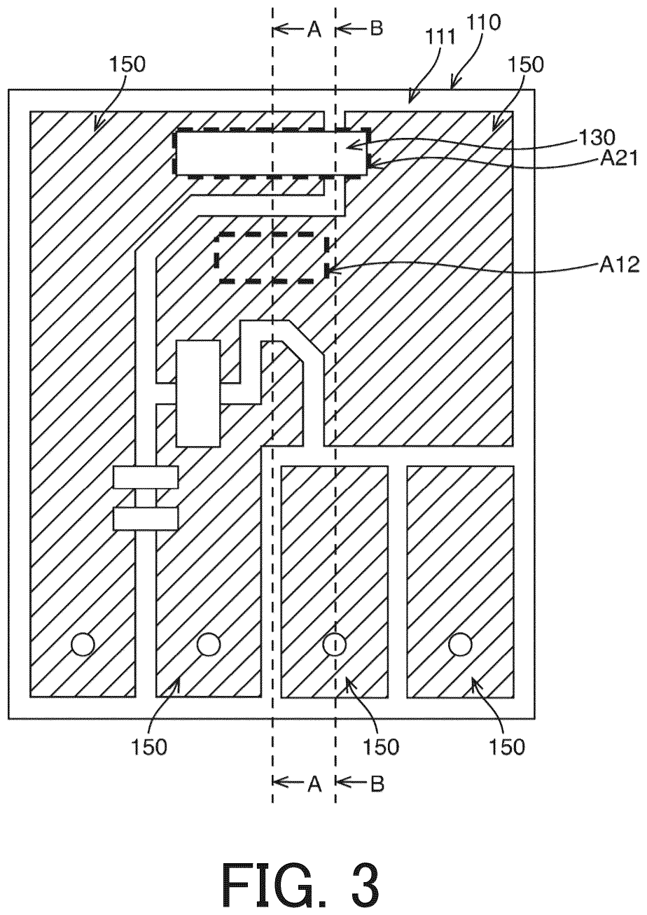

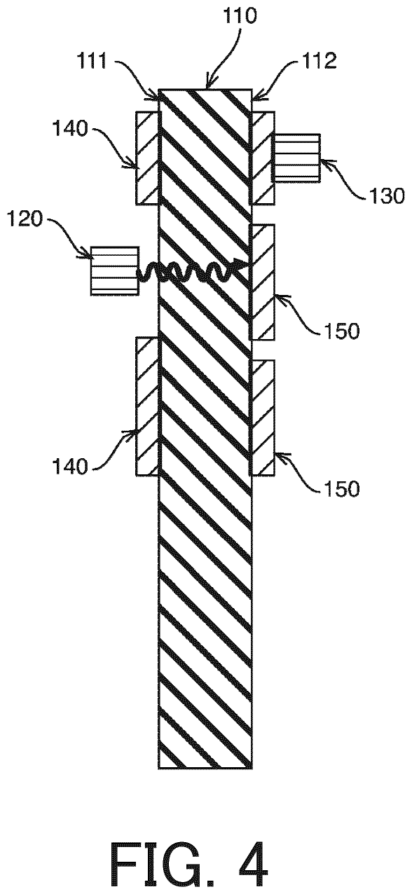

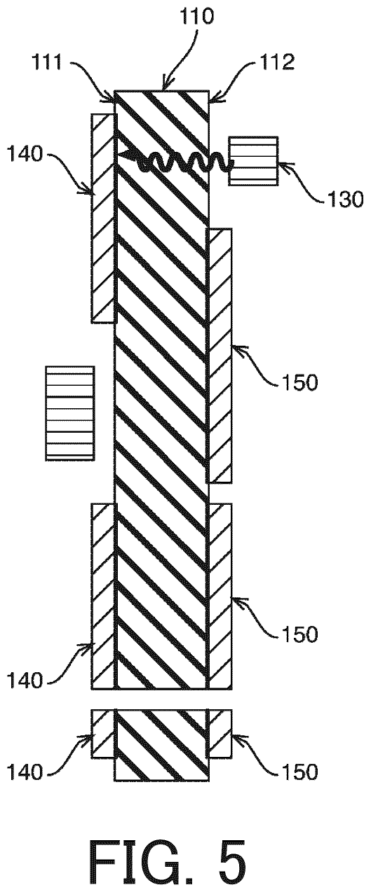

The board 110 is an element having a plate shape and has a first face 111 and a second face 112 opposite to the first face 111. The board 110 is made of an insulator (for example a resin and/or a glass) and transparent for light. FIG. 2 shows a view of the board 110 from its first face 111 side, FIG. 3 shows a view of the board 110 from its second face 112 side, FIG. 4 shows a sectional view of the board 110 according to FIGS. 2 and 3 along the line AA, and FIG. 5 shows a sectional view of the board 110 according to FIGS. 2 and 3 along the line BB.

The first light source 120 and second light source 130 are light sources for emitting light, for example LEDs (light emitting diodes). As shown in FIGS. 2 and 4, the first light source 120 is disposed on the first face 111 of the board 110. As shown in FIGS. 3 to 5, the second light source 130 is disposed on the second face 112 of the board 110.

For example, the first light source 120 and the second light source 130 are intended to be used for different purposes. The first light source 120 is intended to be used e.g. for illumination. The second light source 130 is intended to be used e.g. for an indicator. For example, when the illumination device 100 is configured for illuminating a charging inlet of a vehicle, the first light source 120 is configured for illuminating the charging inlet of the vehicle, wherein the second light source 130 is intended for an indicator, the indicator being configured to indicate a state of charge of the vehicle (for example a state of charge of a battery (for example a main battery) of the vehicle).

The first wiring patterns 140 are used for electrically connecting components arranged on the first face 111 of the board 110 (including the first light source 120). As shown in FIGS. 2, 4 and 5, the first wiring patterns 140 are positioned on the first face 111 of the board 110 so that the first wiring patterns 140 are brought into contact with the first face 111.

The second wiring patterns 150 are used for electrically connecting components arranged on the second face 112 of the board 110 (including the second light source 130). As shown in FIGS. 3 to 5, the second wiring patterns 150 are positioned on the second face 112 of the board 110 so that the second wiring patterns 150 are brought into contact with the second face 112.

The first wiring patterns 140 and second wiring patterns 150 are made of an electrical conductor, and for example patterns of metal foils (e.g. copper foils). The first wiring patterns 140 and second wiring patterns 150 may be made of a same material or made of different materials.

The second wiring pattern 150 of the illumination device 100 according to the present embodiment is disposed so as to cover a region A12 on the second face 112, the region A12 on the second face 112 opposed to a region A11 on the first face 111 with the first light source 120 disposed therein. In this manner, a light emitted from the first light source 120 toward the board 100 is blocked by the second wiring patterns 150, as shown in FIG. 4. This means that according to the present embodiment, even when the light emitted from the first light source 120 toward the board 100 passes through the board, this light is blocked by the second wiring patterns 150. According to the present embodiment, a light coming from the first light source 120 can be prevented from arriving at the second face 112 side of the board 100, for example by providing an element for preventing the light coming from the first light source 120 from arriving at the second face 112 side of the board 100 by circumvention (for example a cover 9 as disclosed in Patent Document 1).

In the above-described manner, the present embodiment enables the light coming from the first light source 120 to be prevented from arriving at the second face 112 side of the board 100. As a result, when the second light source 130 emits no light, the present embodiment enables the second light source 130 side (the second face 112 side of the board 100) to be prevented from being illuminated. Accordingly, only when the second light source 130 is turned on, the present embodiment may allow a user to recognize the fact that the second light source 130 is turned on, wherein when the second light source 130 is not turned on, the user may not recognize that the second light source 130 is turned on.

Therefore, for example when the first light source 120 is intended to be used for illumination and the second light source 130 is intended to be used for an indicator, the present embodiment allows the user to correctly recognize indication of the indicator (indication by the second light source 130) even in the case of the light source for illumination (first light source 120) being turned on. As a result, the present embodiment enables an illumination device to be provided which includes two light sources to be used for different purposes.

Furthermore, the first wiring patterns 140 in the illumination device 100 according to the present embodiment is disposed so as to cover a region A22 on the first face 111, the region A22 on the first face 111 opposed to a region A21 on the second face 112 with the second light source 130 disposed therein. In this manner, a light emitted from the second light source 130 toward the board 100 is blocked by the first wiring patterns 140, as shown in FIG. 5. This means that according to the present embodiment, even when the light emitted from the second light source 130 toward the board 100 passes through the board, this light is blocked by the first wiring patterns 140. According to the present embodiment, a light coming from the second light source 130 can be prevented from arriving at the first face 111 side of the board 100, for example by providing an element for preventing the light coming from the second light source 130 from arriving at the first face 111 side of the board 100 by circumvention (for example the cover 9 as disclosed in Patent Document 1).

In the above-described manner, the present embodiment enables the light coming from the second light source 130 to be prevented from arriving at the first face 111 side of the board 100. As a result, when the first light source 120 emits no light, the present embodiment enables the first light source 120 side (the first face 111 side of the board 100) to be prevented from being illuminated. Accordingly, only when the first light source 120 is turned on, the present embodiment may allow the user to recognize the fact that the first light source 120 is turned on, wherein when the first light source 120 is not turned on, the user may not recognize that the first light source 120 is turned on.

The first light source 120 may be a light source for an indicator, the indicator being configured to indicate first information, wherein the second light source 130 may be a light source for an indicator, the indicator being configured to indicate second information that is different from the first information. Also in such a configuration, the present embodiment enables indications of both indicators for indicating the first information (indication via the first light source 120) and for indicating the second information (indication via the second light source 130) to be correctly recognized by the user.

The present invention has been described above by means of the preferable embodiment thereof. Although the invention has been described herein by presenting a specific example, various modifications and changes may be made to such an example without departing from the spirit and scope of the invention as set forth in the claims.

### REFERENCE SIGNS LIST

100 Illumination device
110 Board
111 First face of the board 110
112 Second face of the board 110
120 First light source
130 Second light source
140 First wiring patterns
150 Second wiring patterns

What is claimed is:

1. An illumination device comprising:
a board having a first face and a second face opposite to the first face;
a first light source disposed on the first face;
a second light source disposed on the second face; and
a second wiring pattern disposed on the second face,
wherein the second wiring pattern is disposed so as to cover a region on the second face, the region on the second face opposed to a region on the first face with the first light source disposed therein.

2. The illumination device as claimed in claim 1, further comprising a first wiring pattern disposed on the first face,
wherein the first wiring pattern is disposed so as to cover a region on the first face, the region on the first face opposed to a region on the second face with the second light source disposed therein.

3. The illumination device as claimed in claim 1,
wherein the first light source and the second light source are intended to be used for different purposes.

4. The illumination device as claimed in claim 2,
wherein the first light source and the second light source are intended to be used for different purposes.

5. The illumination device as claimed in claim 3,
wherein the second light source is intended to be used for an indicator.

6. The illumination device as claimed in claim 4,
wherein the second light source is intended to be used for an indicator.

7. The illumination device as claimed in claim 5,
wherein the first light source is intended to be used for illumination.

8. The illumination device as claimed in claim 6,
wherein the first light source is intended to be used for illumination.

9. The illumination device as claimed in claim 7,
wherein the illumination device is an illumination device configured for illuminating a charging inlet of a vehicle,
wherein the first light source is a light source configured for illuminating the charging inlet of the vehicle, and
wherein the second light source is a light source for an indicator, the indicator being configured to indicate a state of charge of the vehicle.

10. The illumination device as claimed in claim 8,
wherein the illumination device is an illumination device configured for illuminating a charging inlet of a vehicle,
wherein the first light source is a light source configured for illuminating the charging inlet of the vehicle, and
wherein the second light source is a light source for an indicator, the indicator being configured to indicate a state of charge of the vehicle.

11. The illumination device as claimed in claim 2,
wherein the first light source is a light source for an indicator, the indicator being configured to indicate first information, and
wherein the second light source is a light source for an indicator, the indicator being configured to indicate second information that is different from the first information.
